(19) United States
(12) Patent Application Publication
(10) Pub. No.: US 2024/0112965 A1
(43) Pub. Date: Apr. 4, 2024

(54) TRENCH STRUCTURE FOR SEMICONDUCTOR DEVICE

(71) Applicant: INTERNATIONAL BUSINESS MACHINES CORPORATION, ARMONK, NY (US)

(72) Inventors: Chinami Marushima, Urayasu-city (JP); Toyohiro Aoki, Yokohama (JP); Takashi Hisada, Hachiouji-shi (JP); Marc A. Bergendahl, Rensselaer, NY (US)

(21) Appl. No.: 17/937,764

(22) Filed: Oct. 3, 2022

(51) Int. Cl. H01L 23/13; H01L 21/56; H01L 23/00; H01L 23/538; H01L 25/065

(52) U.S. Cl. CPC H01L 23/13; H01L 21/563; H01L 23/5381; H01L 23/5386; H01L 24/16; H01L 24/32; H01L 24/73; H01L 24/81; H01L 25/0652; H01L 23/145

(57) ABSTRACT

A semiconductor device includes a substrate, which further includes a cavity and a trench extended from the cavity. The semiconductor includes a first chip and a second chip on the substrate, a bridge chip interconnecting between the first and second chips and residing in the cavity, and underfill material filling the cavity and the trench, and surrounding the bridge chip.

### BACKGROUND

### Technical Field

The present disclosure generally relates to a semiconductor device and more particularly to a trench structure configured to prevent from void entrapment in a semiconductor device and methods of creation thereof.

### Description of the Related Art

Since it is often desirable to minimize the size of an electronic apparatus, surface mount semiconductor devices may frequently be utilized because of their compact footprints. An integrated circuit (IC) may typically be attached to a substrate using solder nodules or “bumps” that may have spherical, near-spherical, or other geometries. The contact points or bond pads on the IC and substrate are corresponding metallized places. Usually, optical alignment equipment may be used to align the components. Connections may be created between the contact points by heating. Often the gap between the IC and substrate may filled with a dielectric underfill material. The IC assembly may then generally be encapsulated in a protective plastic package to provide increased strength and protection.

### SUMMARY

According to an embodiment of the disclosure, a semiconductor device comprising a trench structure configured to aid in a capillary underfill process is provided. The semiconductor device comprises a substrate, which further comprises a cavity and a trench extended from the cavity. There is a first chip and a second chip on the substrate, a bridge chip interconnecting between the first and second chips and residing in the cavity, and underfill material filling the cavity and the trench, and surrounding the bridge chip.

According to another embodiment of the present disclosure, a method of assembling a semiconductor device is provided. A substrate is provided. A cavity is machined and a trench extended from the cavity on the substrate. A first chip, a second chip, and a bridge chip are provided. The bridge chip is bonded to the first and second chips to interconnect the first and second chips. The first and second chips interconnected by the bridge chip are placed on the substrate to reside the bridge chip in the cavity. The first and second chips are bonded to the substrate, and the underfill material is filled, through the trench, into the cavity to surround the bridge chip in the cavity.

In one embodiment, the trench is dimensioned as an ingress channel to provide a path for the underfill material to fill the cavity from a first side of the cavity.

In one embodiment, the trench is dimensioned as an outflow channel to provide a path for air to leave the cavity from a second side of the cavity.

The techniques described herein may be implemented in a number of ways. Example implementations are provided below with reference to the following figures.

### BRIEF DESCRIPTION OF THE SEVERAL VIEWS OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A depicts a cross sectional view of a semiconductor device in accordance with an illustrative embodiment.

FIG. 1B depicts a top view of a semiconductor device in accordance with an illustrative embodiment.

FIG. 1C depicts a cross sectional view of a semiconductor device in accordance with an illustrative embodiment.

FIG. 2A depicts a top view of a semiconductor device in showing a trench structure in accordance with an illustrative embodiment.

FIG. 2B depicts a top view of a semiconductor device in showing an underfill dispense pattern in accordance with an illustrative embodiment.

FIG. 3A depicts a top view of a semiconductor device in showing a trench structure in accordance with an illustrative embodiment.

FIG. 3B depicts a top view of a semiconductor device in showing an underfill dispense pattern in accordance with an illustrative embodiment.

FIG. 4A depicts a top view of a semiconductor device in showing trench structures in accordance with an illustrative embodiment.

FIG. 4B depicts a top view of a semiconductor device in showing an underfill dispense pattern in accordance with an illustrative embodiment.

FIG. 5A depicts a top view of a semiconductor device in showing a trench structure in accordance with an illustrative embodiment.

FIG. 5B depicts a cross sectional view of a semiconductor device showing a through hole in accordance with an illustrative embodiment.

FIG. 6A depicts a cross sectional view of a semiconductor device showing a first trench structure variation in accordance with an illustrative embodiment.

FIG. 6B depicts a cross sectional view of a semiconductor device showing a second trench structure variation in accordance with an illustrative embodiment.

FIG. 6C depicts a cross sectional view of a semiconductor device showing a third trench structure variation in accordance with an illustrative embodiment.

FIG. 6D depicts a cross sectional view of a semiconductor device showing a fourth trench structure variation in accordance with an illustrative embodiment.

FIG. 7A depicts a cross sectional view of a semiconductor device showing a first trench structure variation in accordance with an illustrative embodiment.

FIG. 7B depicts a cross sectional view of a semiconductor device showing a second trench structure variation in accordance with an illustrative embodiment.

FIG. 7C depicts a cross sectional view of a semiconductor device showing a third trench structure variation in accordance with an illustrative embodiment.

FIG. 7D depicts a cross sectional view of a semiconductor device showing a fourth trench structure variation in accordance with an illustrative embodiment.

FIG. 8A depicts a top view of a semiconductor device showing an underfill flow process in accordance with an illustrative embodiment.

FIG. 8B depicts a top view of a semiconductor device showing a timeline of an underfill flow process in accordance with an illustrative embodiment.

FIG. 9A depicts a top view of a semiconductor device showing an underfill flow process in accordance with an illustrative embodiment.

FIG. 9B depicts a top view of a semiconductor device showing a timeline of an underfill flow process in accordance with an illustrative embodiment.

FIG. 10A depicts a top view of a semiconductor device showing an underfill flow process in accordance with an illustrative embodiment.

FIG. 10B depicts a top view of a semiconductor device showing a timeline of an underfill flow process in accordance with an illustrative embodiment.

FIG. 11A depicts a top view of a trench and cavity in accordance with an illustrative embodiment.

FIG. 11B depicts a cross sectional view of a semiconductor device in accordance with an illustrative embodiment.

FIG. 12A depicts a top view of a trench and cavity in accordance with an illustrative embodiment.

FIG. 12B depicts a cross sectional view of a semiconductor device in accordance with an illustrative embodiment.

FIG. 13 depicts a process for assembling a semiconductor device, in accordance with one embodiment.

FIG. 14 depicts a functional block diagram of a computer hardware platform in accordance with one embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below”, or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to trench structures for semiconductor devices. The illustrative embodiments recognize that in assemblies a gap may remain between the components and the substrate. If the gap is not underfilled, the component and substrate may suffer from fatigue cracking and electrical failure when the entire structure is subjected to high-temperature or other stress conditions. An underfill material, such as a type of resin, may be applied between the surface of the component and the substrate to fill the gap and thereby provide structural reinforcement. The illustrative embodiments recognize that as the size of components continues to decrease, it may become increasingly difficult to apply the underfill material to fill the gaps between the chips and the substrate. Furthermore, a semiconductor device may have an additional cavity in between the components and the substrate. The illustrative embodiments recognize that effectively controlling underfill material flow in such a device while preventing the formation of void entrapments is a highly complex undertaking.

The illustrative embodiments disclose a semiconductor device comprising a cavity that houses a bridge chip. The semiconductor device may be, for example, a Direct Bonded Heterogeneous Integration (DBHi) package. The semiconductor device may comprise one or more trenches configured to prevent void entrapment and to control flow of underfill material into or out of not only the gaps between first and second chips connected by a bridge chip and the substrate but also the gaps between the cavity and bridge chip. One may recognize that it may be difficult to fill gaps between a cavity and a bridge with underfill material. The trenches may aid in the underfill flow and/or air evacuation for underfill flow.

In one embodiment, a trench is designed as a supply mechanism or ingress in which underfill material may fed by capillary action to prevent void entrapment. The dimensions of the trench may be based on a viscosity of the underfill used. The trench may be designed as an outflow channel for underfill outflow or air evacuation wherein air may escape though the trench in an end opposite another end from which underfill material arrives. Thus, if the underfill material does not flow into the cavity before flowing into an entire gap area between chips and substrate, the outflow trench may enable air flow out of cavity. An ingress channel may in some cases function as an outflow channel. Further, by picking a thin underfill from a viscosity standpoint, a narrower trench may be needed and vice versa.

In one embodiment, a trench depth may be configured to be equal to a depth of the cavity when the trench is used as a path for underfill material to flow into cavity, whereas when the trench is used as a path for underfill material to flow out of cavity, configuring the trench depth to be at least half of the cavity depth may be enough to reduce void entrapment.

In one embodiment a DBHi package maybe used wherein the width of the trench may be larger than 0.2 mm in the DBHi package structure the underfill to flow into cavity. Although in a non-molded or non-tiled sub-assembly the trench structure provides an advantage with the underfill filling process, in the case of a molded or tiled sub-assembly the advantage become much higher because the underfill material may not naturally flow into the cavity without the trench structure. When the cavity is machined on the substrate, the trench structure is also machined.

### Example Architecture

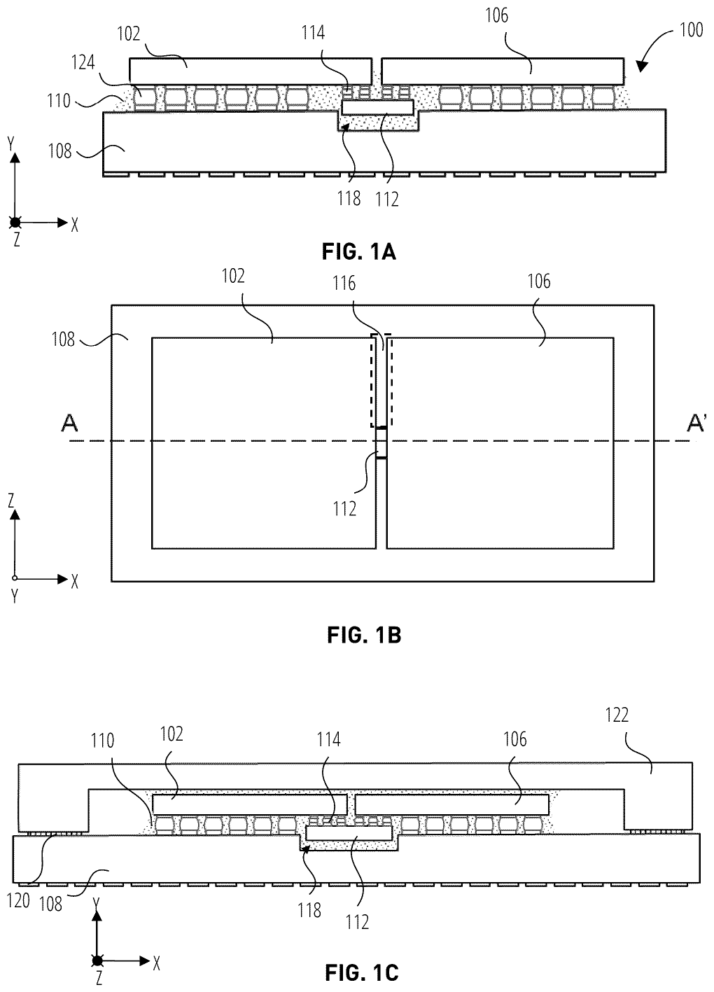

FIG. 1A illustrates a cross section (A-A′) of a semiconductor device 100 that may comprise a substrate 108 such as an organic laminate comprising a cavity 118 and a trench 116 (shown in FIG. 1B) extended from the cavity. The semiconductor device 100 may also comprise a first chip 102 and a second chip 106 on the substrate 108, a bridge chip 112 interconnecting between the first and second chips and residing in the cavity 118, and underfill material 110 filling the cavity 118 and the trench 116 and surrounding the bridge chip 112. In some embodiments, the bridge chip 112 may be bonded to the first and second chips by pillars such as Cu pillars 114 or micro C4 bumps. The first and second chips may also be bonded to the substrate by C4 bumps 124. The trench 116 extending from the cavity may be machined. By machining the trench 116 in the cavity 118, additional assembly processes and pressure vacuums or pressure cure which may be used to reduce voids may not be needed.

FIG. 1B illustrates a top view of the semiconductor device 100 showing a position of the trench 116 and of the bridge chip 112 that interconnects the first chip 102 and the second chip 106. As shown in FIG. 1C, the semiconductor device 100 may also have a lid 122 and lid adhesive 120 bonding the lid 122 to the substrate 108.

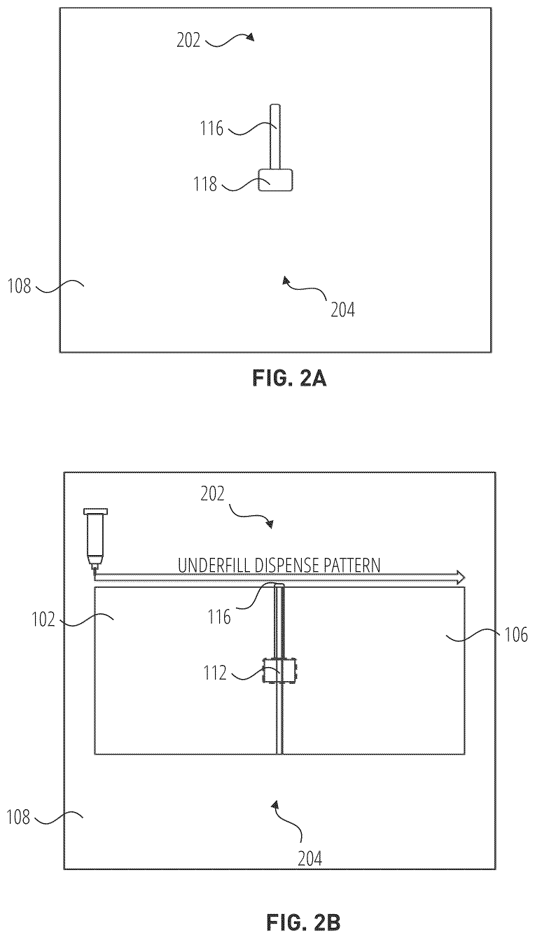

Turning to FIG. 2A and FIG. 2B, a top view of a semiconductor device is shown. FIG. 2A shows the top view without the first and second chips. The trench 116 extends from the cavity 118 at a first side 202 of the cavity. In an underfill process, as shown in FIG. 2B which also depicts the first and second chips, underfill material may be dispensed in a pattern starting at the first side 202. Underfill material 110 may thus flow into the trench as a result before reaching the second side 204 of the cavity opposite the first side 202.

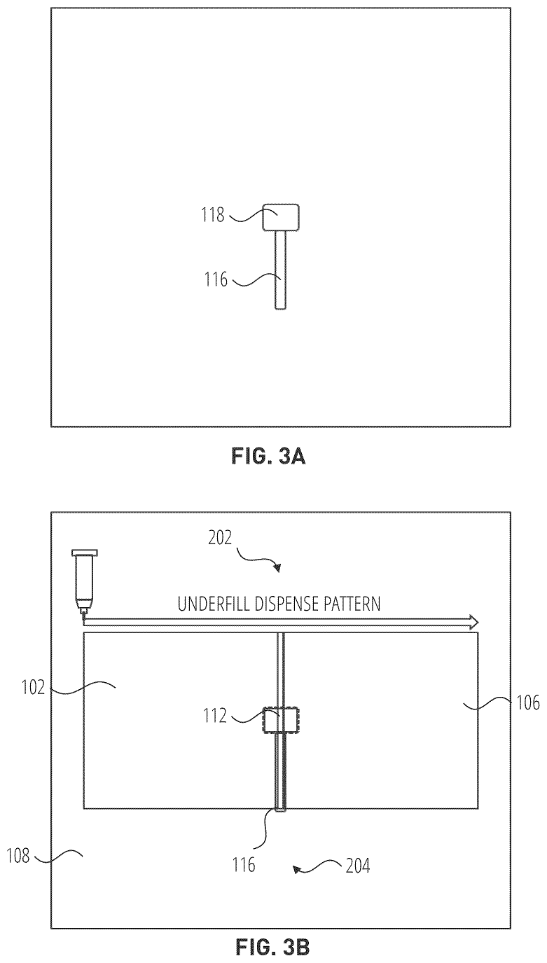

FIG. 3A and FIG. 3B also show a top view of a semiconductor device comprising at least a cavity 118 and a trench 116. As shown in FIG. 3B, the trench 116 may extend from the cavity 118 at a second side 204 of the cavity 118 opposite the first side 202. In an underfill process, as shown in FIG. 3B, which also depicts the first chip 102 and second chip 106, underfill material may be dispensed in a pattern starting at the first side 202. The trench may thus provide a channel for outflow of air as the underfill material moves from the first side 202 towards the second side 204. Underfill material 110 may thus flow into the trench 116 at the second side which evacuating air to avoid void entrapment.

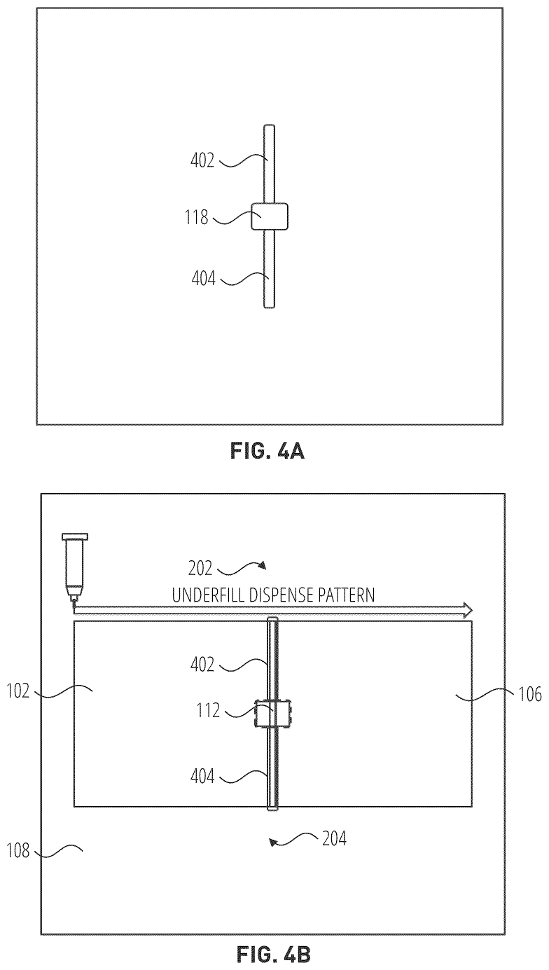

In one embodiment, as shown in FIG. 4A and FIG. 4B, the semiconductor device comprises a first trench 402 and a second trench 404 disposed on opposite sides of the cavity 118. By dispensing the underfill material in the pattern shown in FIG. 4B, the first trench may receive the underfill material before the underfill material reaches the second trench 404. The combination of first and second trenches may further enhance the prevention of void entrapments.

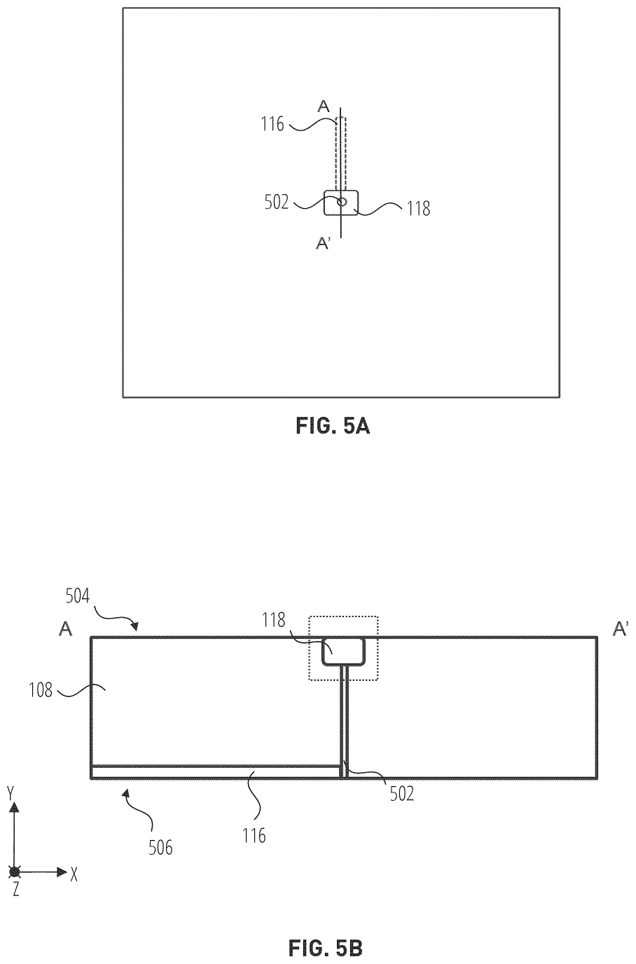

FIG. 5A and FIG. 5B illustrate an embodiment of the semiconductor device further comprising a through hole 502. As shown in FIG. 5B, the trench 116 may be disposed at a bottom surface 506 of the substrate 108, opposite a top surface 504 where the cavity is disposed. The through hole 502 may enable the underfill material to pass through from the to or from the trench 116.

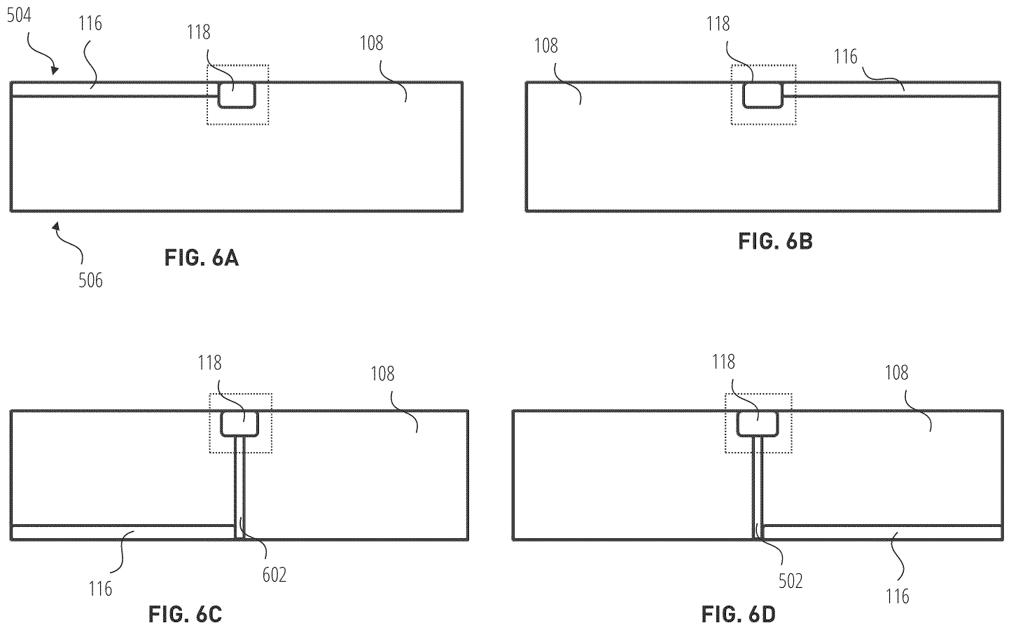

Thus, while the while the trench 116 may in some embodiments be disposed at a top side on either side of the cavity as shown in FIG. 6A and FIG. 6B, the trench may also be disposed on a bottom surface 506 of the substrate with an interconnecting through hole 502 as shown in FIG. 6C and FIG. 6D. If the trench is an outflow trench, it may interfere with a land grid array or ball grid array interconnect. Thus, the location of the trench on the substrate/laminate may be altered accordingly.

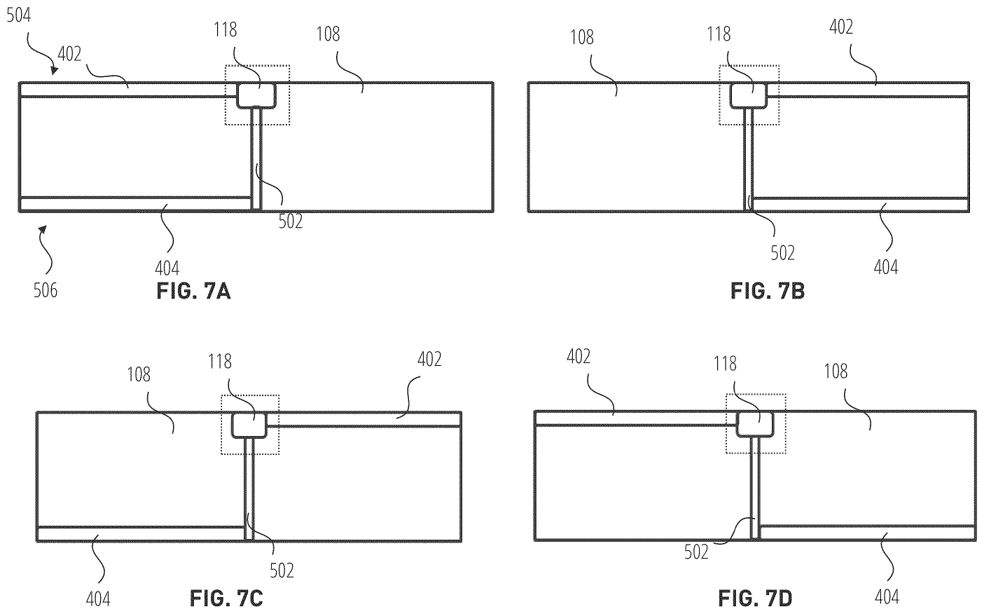

In other illustrative embodiments as shown in FIG. 7A-FIG. 7D, two trenches, a first and a second trench may be arranged in various configurations on a top surface 504 and a bottom surface 506 of the substrate 108. In all cases, the first trench 402 which may be located on the top surface 504 may be connected to the second trench 404 which may be located on bottom surface 506. The first trench 402 may be disposed on either side of the cavity in the top surface 504 and the second trench 404 may be located on either side of the through hole on the bottom surface 506.

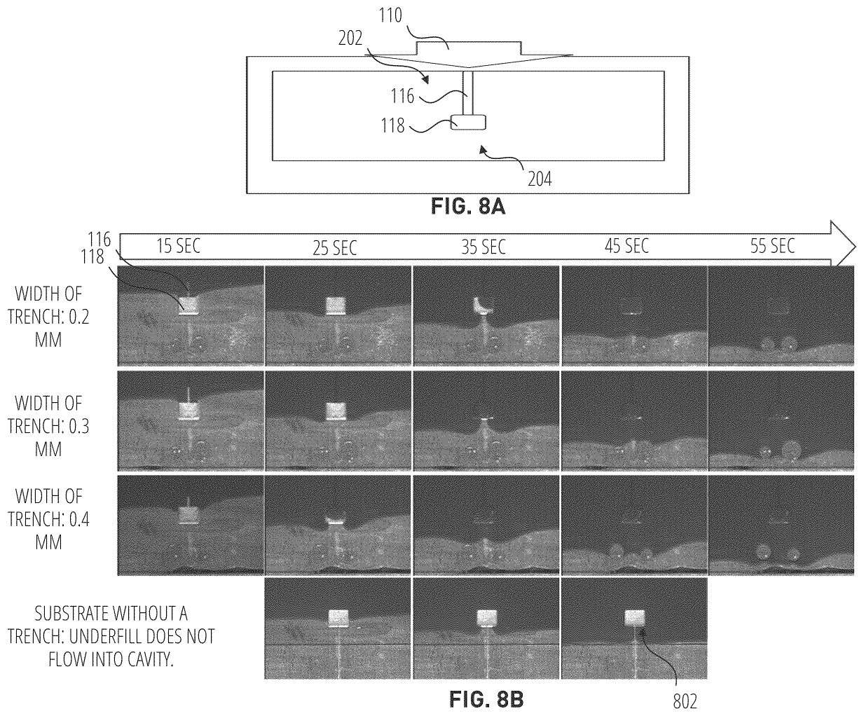

Turning now to FIG. 8A, a study of an underfill process based on a semiconductor device comprising a trench 116 disposed at a first side 202 of the cavity 118 is illustrated. Underfill material was dispensed at the first side 202 of the cavity. Dimensions of trenches of the study are shown below in Table 1. In particular, the trench lengths and trench depths remained constant at 8.125 mm and 0.22 mm respectively and the underfill material flow was observed for changing widths.

TABLE 1
Trench dimensions - First side of cavity

| | Trench design | | |
|---|---|---|---|
| Trench No. | Width | Length | Depth |
| #1 | 0.2 mm | 8.125 mm | 0.22 mm |
| #2 | 0.3 mm | 8.125 mm | 0.22 mm |
| #3 | 0.4 mm | 8.125 mm | 0.22 mm |

As shown in FIG. 8B the flow of underfill material with increasing time in trenches 1, 2 and 3 were observed and may be compared to underfill material flow with increasing time in a substrate/laminate without a trench. It can be seen that in substrates without a trench, the underfill material does not flow into the cavity 118, resulting in void entrapment in the cavity 118 whereas underfill material flows into the cavity without void entrapment, when the substrate has a trench. Further, the larger the width of trench, the more easily underfill material enters the cavity with time.

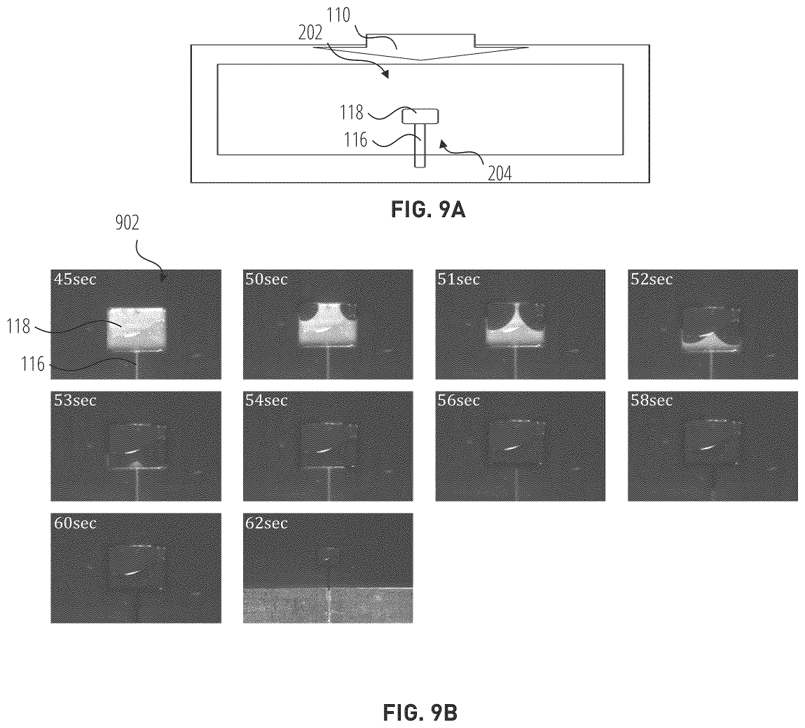

Turning to FIG. 9A, a study of an underfill process based on a semiconductor device comprising a trench 116 disposed at a second side 204 of the cavity 118 is illustrated. Underfill material was dispensed at the first side 202 of the cavity. Dimensions of the trench of the study are shown below in Table 2. In particular, the trench length and trench depth and trench width were 8.125 mm, 0.22 mm, and 0.2 mm respectively and the underfill material flow was observed.

TABLE 2
Trench dimensions - Second side of cavity

| | Trench design | | |
|---|---|---|---|
| Trench No. | Width | Length | Depth |
| #1 | 0.2 mm | 8.125 mm | 0.22 mm |

As can be seen in the results of FIG. 9B, when the substrate has the trench structure for underfill material to flow out of the cavity, the underfill material flows into the cavity even after the C4 area 902 is completely filled with UF. It can be observed that after filling the entire cavity with underfill material, the underfill material flows in the trench at the second side 204 of the cavity.

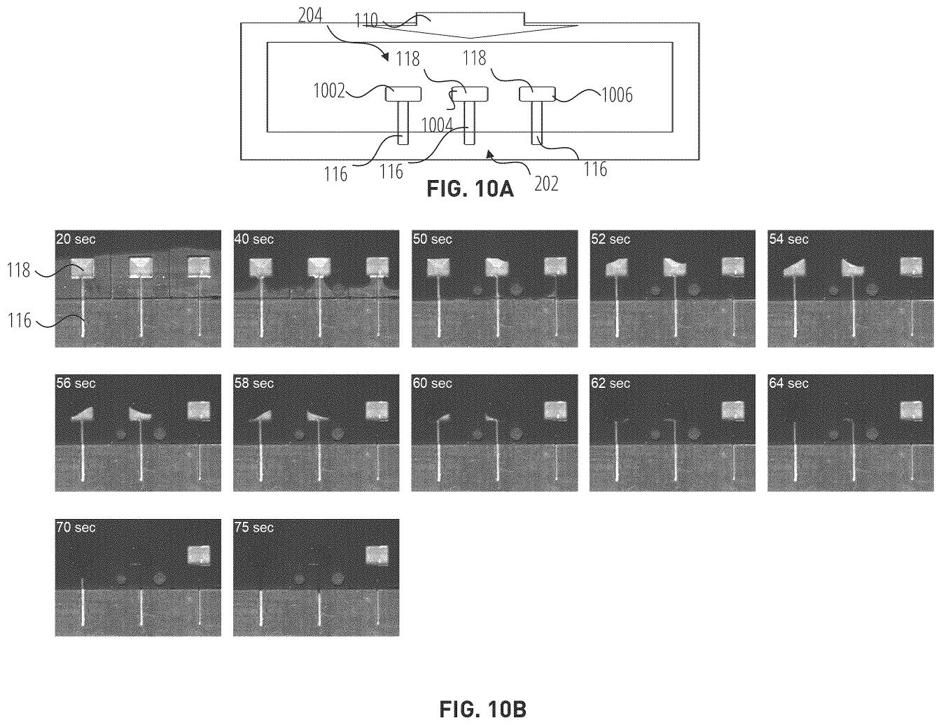

Turning to FIG. 10A, a study of an underfill process based on a semiconductor device comprising three trenches disposed at a second side 204 of the cavity 118 is illustrated. The three trenches correspond to three cavities: cavity #1 1002, cavity #2 1004 and cavity #3 1006. Underfill material was dispensed at the first side 202 of the cavities. Dimensions of the trenches corresponding to the cavities are shown below in Table 3.

TABLE 3
Trench dimensions - Second side of cavities

| | Trench design | | |
|---|---|---|---|
| Cavity No. | Width | Length | Depth |
| Cavity #1 1002 | 0.4 mm | 8.125 mm | 0.21 mm |
| Cavity #2 1004 | 0.3 mm | 8.125 mm | 0.135 mm |
| Cavity #3 1006 | 0.2 mm | 8.125 mm | 0.06 mm |

As shown in the results of FIG. 10B, when the trench depth is 135 μm or larger, as is the case for cavity #2 1004 and cavity #1 1002, the corresponding trench prevents the formation of void entrapments unlike that of cavity #3 1006 for which a void entrapment remains even after 56-75 seconds and beyond. The cavity depth was 0.27 mm for the cavities. This result indicates that the trench depth may be configured to be at least half of cavity depth.

The illustrative embodiments thus recognize from these experiments that by dimensioning the trench appropriately, capillary action may be utilized to ensure the flow of underfill material and prevent void entrapments. Herein, the dimensions may be chosen such that the force dragging the underfill material into the cavity may be to be larger than the force dragging the underfill material into the trench.

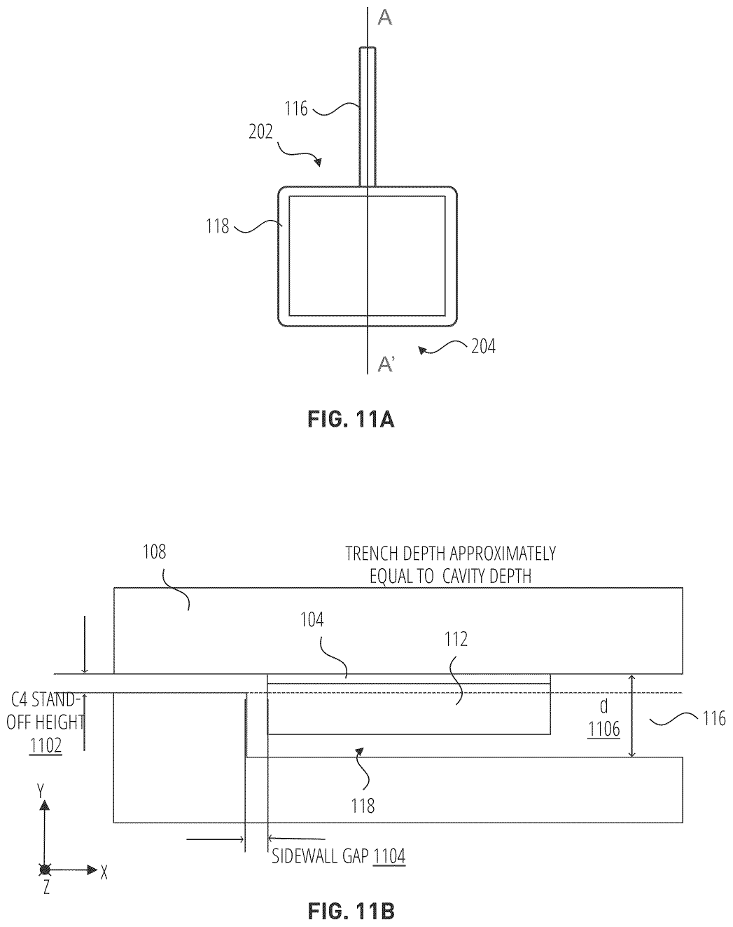

FIG. 11A-FIG. 11B illustrate appropriate dimensioning in a case wherein the trench 116 is disposed on a first side 202 of the cavity 118 and used as an ingress trench in a semiconductor device, consistent with an illustrative embodiment. FIG. 11B further shows a C4 stand-off height 1102, a sidewall gap 1104, and a trench depth d 1106. As seen in FIG. 11B, which shows a cross section (A′-A), the trench depth d 1106 may be equal or substantially equal to the depth of the cavity (in the Y-direction).

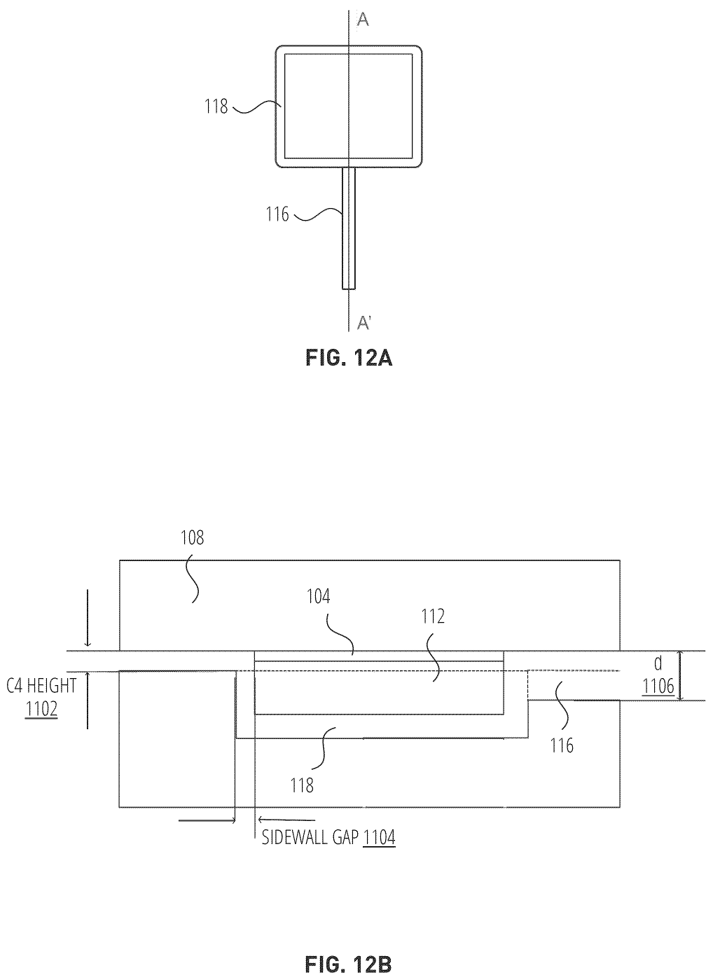

FIG. 12A and FIG. 12B, illustrate a trench 116 disposed on a second side 204 of the cavity 118 and used as an outflow trench. FIG. 12B depicts a cross section (A-A′). The trench depth d 1106 of FIG. 12B may be obtained as follows:
d>sidewall gap

The depth of the trench may be at least half of the depth of the cavity for the underfill material to be able to flow out of the cavity and prevent void entrapment. The depth of the trench may also be dependent on the viscosity and the depth of the cavity and the thickness of the bridge chip and how far it protrudes into the cavity.

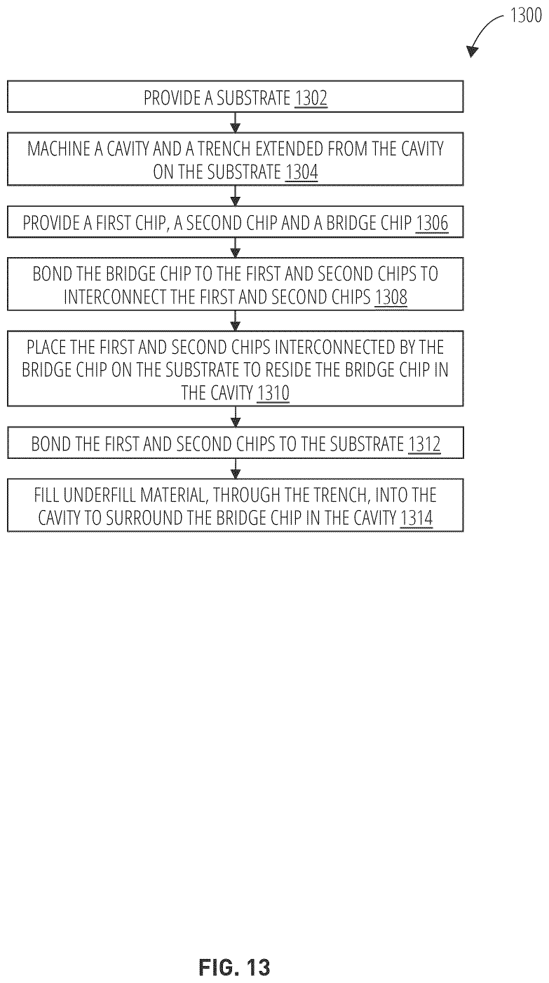

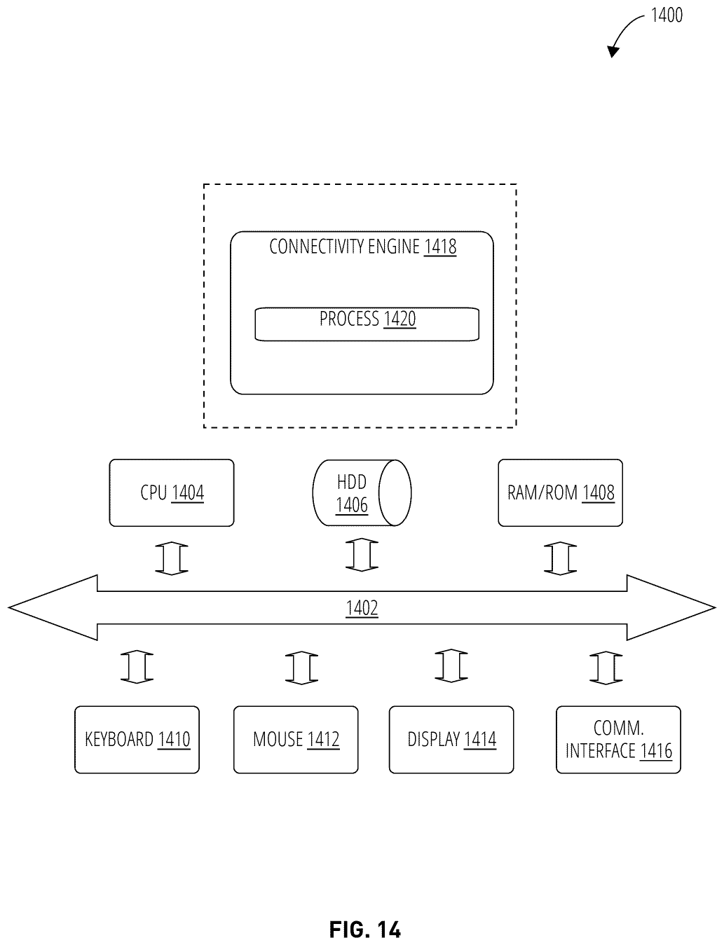

FIG. 13 illustrates a process 1300 in accordance with an embodiment. A whole or part of the process may be performed with the connectivity engine 1418 of FIG. 14. The process 1300 may begin at block 1302, therein a substrate may be provided. In block 1304, connectivity engine 1418 may machine a cavity and a trench extended from the cavity on the substrate. In block 1306, the connectivity engine 1418 may provide a first chip, a second chip and a bridge chip. In block 1308, the connectivity engine 1418 may bond the bridge chip to the first and second chips to interconnect the first and second chips. In block 1310, the connectivity engine 1418 may place the first and second chips interconnected by the bridge chip on the substrate to reside the bridge chip in the cavity. In block 1312, the connectivity engine 1418 may bond the first and second chips to the substrate. In block 1314, the 1418 may fill underfill material, through the trench, into the cavity to surround the bridge chip in the cavity.

The process 1300 may further comprise dimensioning a depth of the trench based on C4 stand-off C4 stand-off height 1102, cavity size, or material viscosity. A width of the trench may be chosen based on a viscosity of the underfill material. For example, a thin underfill material from a viscosity standpoint, may elicit a narrower trench, and a thicker underfill material may elicit a wider trench. In another example, the trench depth is equal to the cavity depth in one case and at least half of the cavity depth in another case and when the trench depth is designed, the optimal dimension may depend on other package dimensions, and material properties.

In another aspect of the process 1300, the substrate of the semiconductor device may be machined to have includes a plurality of trenches. The width of a trench may be larger than 0.2 mm. Further, an epoxy underfill material may be utilized. The semiconductor device may be a direct bonded heterogeneous integration package.

The semiconductor device may also include where the trench is disposed at a bottom of the cavity and extends from the cavity via a through hole.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Example Computer Platform

As discussed above, functions relating to methods and systems for providing trench structures can use of one or more computing devices connected for data communication via wireless or wired communication. FIG. 14 is a functional block diagram illustration of a computer hardware platform that can be used to control various aspects of a suitable computing environment in which the process discussed herein can be controlled. While a single computing device is illustrated for simplicity, it will be understood that a combination of additional computing devices, program modules, and/or combination of hardware and software can be used as well. The computer platform 1400 may include a central processing unit (CPU) 1404, a hard disk drive (HDD) 1406, random access memory (RAM) and/or read only memory (ROM) 1408, a keyboard 1410, a mouse 1412, a display 1414, and a communication interface 1416, which are connected to a system bus 1402.

In one embodiment, the hard disk drive (HDD) 1406, has capabilities that include storing a program that can execute various processes, such as the connectivity engine 1418, in a manner described herein. The connectivity engine 1418 may have various modules configured to perform different functions. For example, there may be a process module 1420 configured to control the different manufacturing processes discussed herein and others.

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising;
a substrate comprising a cavity and a trench extended from the cavity;
a first chip and a second chip on the substrate;
a bridge chip interconnecting between the first and second chips and residing in the cavity; and
an underfill material filling the cavity and the trench, and surrounding the bridge chip.

2. The semiconductor device of claim 1, wherein the trench is dimensioned as an ingress channel to provide a path for the underfill material to fill the cavity from a first side of the cavity.

3. The semiconductor device of claim 2, wherein a depth of the trench is equal to the depth of the cavity.

4. The semiconductor device of claim 1, wherein the trench is dimensioned as an outflow channel to provide a path for air to leave the cavity from a second side of the cavity.

5. The semiconductor device of claim 4, wherein the depth of the trench is at least half of the depth of the cavity.

6. The semiconductor device of claim 1, wherein a depth of the trench is a factor of C4 stand-off height, cavity size, or material viscosity.

7. The semiconductor device of claim 1, further comprising additional one or more trenches, wherein the trench and the additional one or more trenches form a plurality of trenches.

8. The semiconductor device of claim 7, wherein:
the plurality of trenches includes a trench disposed at a first side of the cavity as a first trench; and
a second trench is disposed on a second side of the cavity opposite the first side.

9. The semiconductor device of claim 7, wherein the plurality of trenches are two trenches disposed at a top and bottom portion of the substrate on a same side of the cavity and connected by a though hole.

10. The semiconductor device of claim 7, wherein the plurality of trenches are two trenches disposed at a top and bottom portion of the substrate on opposite sides of the cavity and connected by a through hole.

11. The semiconductor device of claim 1, wherein a width of the trench is larger than 0.2 mm.

12. The semiconductor device of claim 1, wherein the semiconductor device is a direct bonded heterogeneous integration package.

13. The semiconductor device of claim 1, wherein the trench is disposed at a bottom of the cavity and extends from the cavity via a through hole.

14. The semiconductor device of claim 1, wherein:
the semiconductor device comprises another trench disposed at a bottom of cavity; and
the trench is disposed at a top of the cavity.

15. A method comprising;
assembling a semiconductor device by:
providing a substrate;
machining a cavity and a trench extended from the cavity on the substrate;
providing a first chip, a second chip, and a bridge chip;
bonding the bridge chip to the first and second chips to interconnect the first and second chips;
placing the first and second chips interconnected by the bridge chip on the substrate to dispose the bridge chip in the cavity;
bonding the first and second chips to the substrate; and
filling an underfill material, through the trench, into the cavity to surround the bridge chip in the cavity.

16. The method of claim 15, wherein the bridge chip is bonded to the first and second chips by direct bonded heterogeneous integration.

17. The method of claim 15, wherein:
the trench is dimensioned as an ingress channel; and
the underfill material is dispensed at a same side of the cavity as a location of the trench.

18. The method of claim 15, wherein:
the trench is dimensioned as an outflow channel; and
the underfill material is dispensed at a different side of the cavity opposite to a side that contains the trench.

19. The method of claim 15, further comprising dimensioning a depth of the trench to be equal to a depth of the cavity.

20. The method of claim 15, further comprising dimensioning a depth of the trench to be at least half of a depth of the cavity.
